(19) United States
(12) Patent Application Publication
(10) Pub. No.: US 2015/0041948 A1
(43) Pub. Date: Feb. 12, 2015

(54) SEMICONDUCTOR DEVICE INCLUDING STI STRUCTURE AND METHOD FOR FORMING THE SAME

(71) Applicants: Semiconductor Manufacturing International (Beijing) Corporation, Beijing (CN); Semiconductor Manufacturing International (Shanghai) Corporation, Shanghai (CN)

(72) Inventors: XIANYONG PU, Shanghai (CN); YIQUN CHEN, Shanghai (CN); ZONGGAO CHEN, Shanghai (CN)

(73) Assignees: Semiconductor Manufacturing International (Beijing) Corporation; Semiconductor Manufacturing International (Shanghai) Corporation

(21) Appl. No.: 14/445,377

(22) Filed: Jul. 29, 2014

(30) Foreign Application Priority Data
Aug. 5, 2013 (CN) 201310337314.6

(51) Int. Cl. H01L 21/762; H01L 29/06

(52) U.S. Cl. CPC H01L 21/76235; H01L 29/0649
USPC 257/506; 438/426

(57) ABSTRACT

Semiconductor devices and fabrication methods are disclosed. A mask layer having an opening is formed on a semiconductor substrate. The semiconductor substrate is etched along the opening of the mask layer to form a trench therein. The mask layer is laterally etched from the opening of the mask layer along a top surface of the semiconductor substrate to expose a surface portion of the semiconductor substrate on each side of the opening. A liner oxide layer is formed by a thermal oxidation process on interior surface of the trench and on the exposed surface portion of the semiconductor substrate. The thermal oxidation process is controlled such that an upper corner between the top surface of the semiconductor substrate and the trench is rounded after the liner oxide layer is formed. An insulation layer is formed on the liner oxide layer and fills the trench.

### CROSS-REFERENCES TO RELATED APPLICATIONS

This application claims priority to Chinese Patent Application No. CN201310337314.6, filed on Aug. 5, 2013, the entire content of which is incorporated herein by reference.

### FIELD OF THE DISCLOSURE

The present disclosure relates to the field of semiconductor technology and, more particularly, relates to semiconductor devices having shallow trench isolation (STI) structures and methods for forming the same.

### BACKGROUND

Critical dimensions (CDs) in submicron and smaller are increasingly demanded for next generation VLSI (i.e., very large scale integration) circuits and VLSI semiconductor devices. As CDs increasingly shrink, formation of high quality gate patterns and shallow trench isolation (STI) structures plays important roles in developing integrated circuits (ICs). Insulation effect of STI structures is critical for providing semiconductor chips with desirable reliability.

FIGS. 1-2 depict a conventional method for forming an STI structure. As shown in FIG. 1, mask layer 20 having an opening is fabricated on semiconductor substrate 10. A trench 30 is formed in the semiconductor substrate 10 by etching the semiconductor substrate 10 along the opening in the mask layer 20. In FIG. 2, the trench 30 is filled with an insulating material. The insulating material is planarized using the mask layer as a stop layer to form STI structure 40.

### BRIEF SUMMARY OF THE DISCLOSURE

According to various embodiments, there is provided a method for forming a semiconductor device. A mask layer having an opening is formed on a semiconductor substrate. The semiconductor substrate is etched along the opening of the mask layer to form a trench in the semiconductor substrate. The mask layer is laterally etched along a top surface of the semiconductor substrate from the opening of the mask layer to expose a surface portion of the semiconductor substrate on each side of the opening. A liner oxide layer is formed by a thermal oxidation process on an interior surface of the trench and on the exposed surface portion of the semiconductor substrate on each side of the opening. The thermal oxidation process is controlled such that an upper corner between the top surface of the semiconductor substrate and the trench is rounded after the liner oxide layer is formed. An insulation layer is formed on the liner oxide layer and fills the trench.

According to various embodiments, there is also provided a semiconductor device. The semiconductor device includes a semiconductor substrate and a liner oxide layer disposed on sidewall surfaces and a bottom surface of a trench in the semiconductor substrate. The liner oxide layer is formed by forming a mask layer having an opening on the semiconductor substrate, then etching the semiconductor substrate along the opening of the mask layer to form the trench, laterally etching the mask layer along a top surface of the semiconductor substrate from the opening of the mask layer to expose a surface portion of the semiconductor substrate, and forming the liner oxide layer on an interior surface of the trench and on the exposed surface portion of the semiconductor substrate. The liner oxide layer is formed by a thermal oxidation process controlled such that an upper corner between a top surface of the semiconductor substrate and the trench is a rounded corner after the liner oxide layer is formed. The semiconductor device also includes an insulation layer disposed on the liner oxide layer and fills the trench.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-2 depict a conventional method for forming an STI structure;

FIGS. 3-13 depict an exemplary semiconductor device including an STI structure at various stages during its formation consistent with the disclosed embodiments; and

FIG. 14 depicts an exemplary method for forming a semiconductor device including an STI structure consistent with the disclosed embodiments.

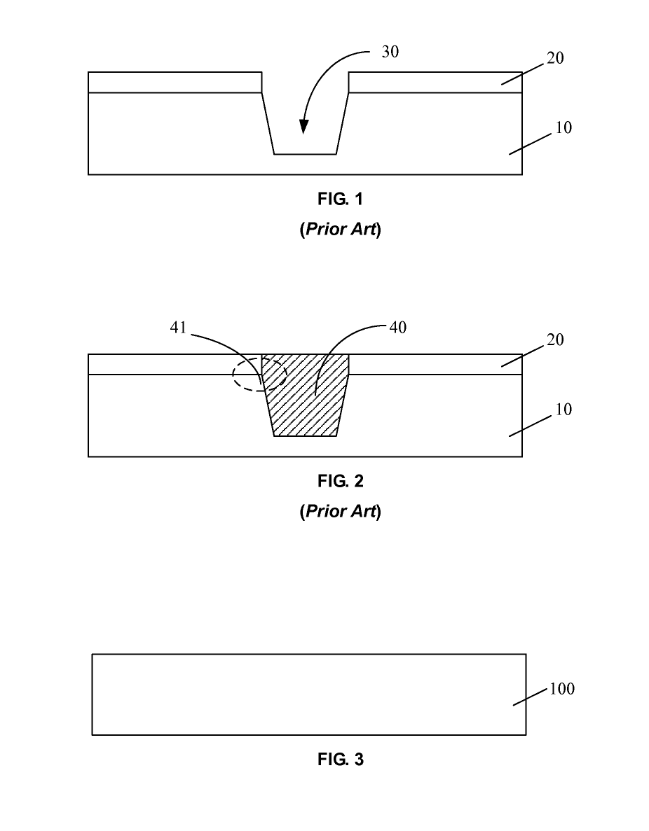

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

For a semiconductor chip including an STI structure, leakage current may occur when operated under high voltages. This reduces reliability of the circuits and causes chip failure. As shown in FIG. 2, leakage current tends to occur at upper corner 41 between semiconductor substrate 10 and STI structure 40 when in operation.

The upper corner 41 between the semiconductor substrate 10 and the STI structure 40 is relatively sharp. Under high voltages, electric field generated at this corner has high density, which causes leakage current. In addition, the sharp upper corner 41 may include a high local stress and deposition quality of the insulating material at the sharp upper corner 41 may be affected when forming the STI structure 40. Isolation performance of the STI structures can also be affected and therefore needs to be improved.

As disclosed herein, an exemplary STI structure can be formed such that the upper corner between the semiconductor substrate and the STI structure can be rounded during STI fabrication processes. Isolation performance of the STI structures can thus be significantly enhanced.

FIGS. 3-13 depict an exemplary semiconductor device including an STI structure at various stages during its formation, while FIG. 14 depicts an exemplary method for forming the semiconductor device including the STI structure consistent with the disclosed embodiments.

Referring to FIG. 3, semiconductor substrate 100 is provided (e.g., in Step 1402).

The semiconductor substrate 100 can be made of a material including silicon, germanium, silicon-germanium, gallium arsenide, and/or other suitable semiconductor materials. The semiconductor substrate 100 can be a bulk material, or can include a composite structure such as silicon-on-insulator (SOI). Depending on devices to be fabricated on the semiconductor substrate, the type of semiconductor substrate 100 can be selected as desired without limitations. Any type of semiconductor substrates can be used for forming the disclosed semiconductor devices.

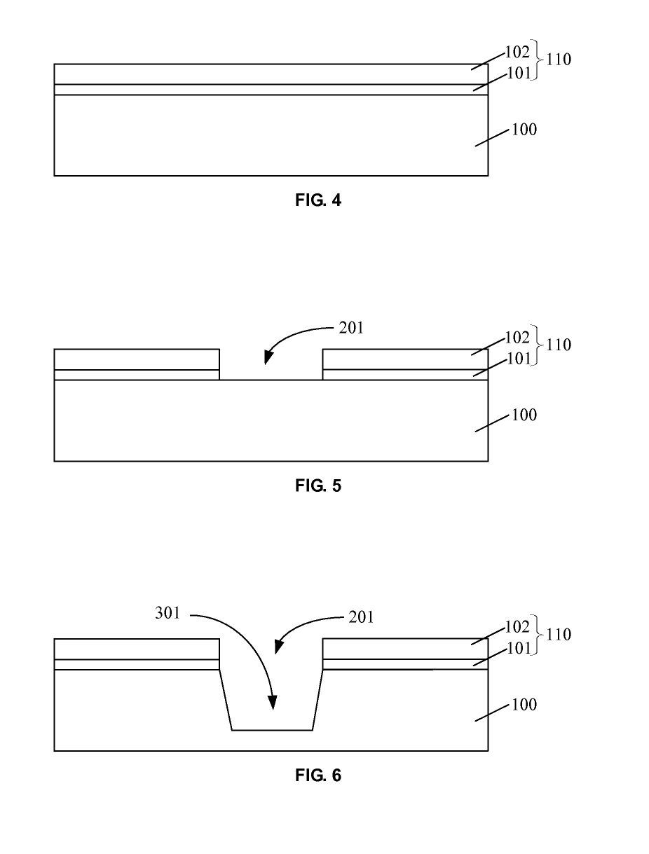

In FIG. 4, mask layer 110 is formed on surface of the semiconductor substrate 100 (e.g., in Step 1404).

In one embodiment, the mask layer 110 can include a silicon oxide layer 101 formed on a top surface of the semiconductor substrate 100, and a silicon nitride layer 102 formed on surface of the silicon oxide layer 101. In another embodiment, the mask layer 110 can be fabricated with any other suitable mask material(s). The mask layer 110 can be a single layer.

The silicon oxide layer 101 can be used as a buffer layer for the subsequently formed silicon nitride layer 102. In the case when the silicon nitride layer 102 is directly fabricated on surface of the semiconductor substrate 100, dislocations may be generated on surface of the semiconductor substrate 100 due to large stress generated in the silicon nitride layer 102. By forming the silicon oxide layer 101 between the semiconductor substrate 100 and the silicon nitride layer 102, defects generated due to dislocations between these two layers can be resolved. In addition, the silicon oxide layer 101 can also be used as an etch stop layer when the silicon nitride layer 102 is subsequently etched. The silicon oxide layer 101 can be fabricated by wet oxidation or dry oxidation. The thickness of the silicon oxide layer 101 can range from about 5 Å to about 1000 Å, for example from about 5 Å to about 100Å.

The silicon nitride layer 102 can serve as a stop layer for a subsequent chemical mechanical polishing (CMP) process. The silicon nitride layer 102 can be fabricated by, e.g., chemical vapor deposition. The thickness of the silicon nitride layer 102 can range from about 100 Å to about 3000 Å, for example from about 100 Å to about 1000 Å.

Referring to FIG. 5, the mask layer 110 is patterned to include opening 201 formed through the mask layer 110 to expose a surface portion of the semiconductor substrate 100 (e.g., in Step 1404).

The opening 201 can be made by, e.g., a dry etching process. For example, a patterned photoresist layer (not shown) having a pattern corresponding to the opening 201 can be formed on top of the silicon nitride layer 102. The patterned photoresist layer can be used as a mask for etching silicon nitride layer 102 and silicon oxide layer 101, e.g., by a dry etching (including a plasma etching) process to form the opening 201. After the opening 201 is formed, the patterned photoresist layer can be removed by, e.g., an ashing process or a chemical solvent.

The opening 201 can have a width ranging from about 5 nm to about 100 nm. The position of the opening 201 can define locations of subsequently-formed STI structure.

Referring to FIG. 6, trench 301 is formed in the semiconductor substrate 100 by etching the semiconductor substrate 100 through the opening 201 (e.g., in Step 1406).

The semiconductor substrate 100 can be etched by, e.g., a dry etching process, using the mask layer 110 as an etch mask. In one embodiment, the semiconductor substrate 100 can be etched, e.g., by a plasma etching. The trench 301 can have a thickness greater than or equal to about 10 nm. Insulating materials can be filled into the trench 301 to form STI structure(s).

In one embodiment, use of dry etching to from the trench can provide a fast etching rate at a top portion of the trench. As a result, the formed trench 301 can have an inclined sidewall. In other embodiments, the trench 301 in the semiconductor substrate 100 can have a vertical sidewall, Σ-shaped sidewall, or any other suitable sidewalls.

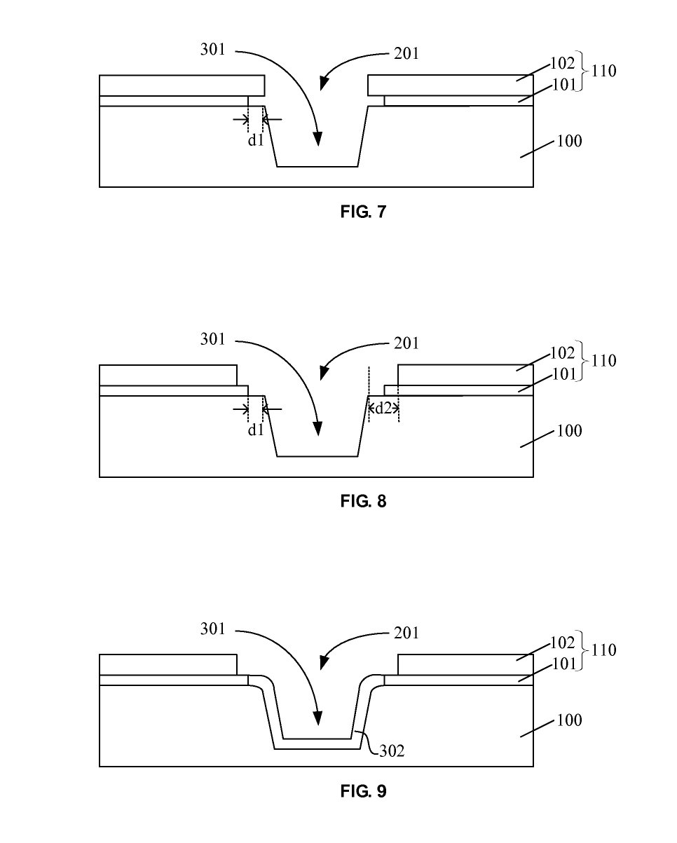

Referring to FIG. 7, the silicon oxide layer 101 disposed between the semiconductor substrate 100 and the silicon nitride layer 102 can be laterally etched on both sides of the opening 201 to expose a surface portion of the semiconductor substrate 100 (e.g., in Step 1408).

When laterally etching the silicon oxide layer 101 along the top surface of the semiconductor substrate 100, a wet etching process can be performed using, e.g., hydrofluoric acid solution. The silicon oxide layer 101 can be laterally etched to remove a portion of the silicon oxide layer 101 to expose surface portions of the semiconductor substrate 100 on both sides of the opening 201. For example, the laterally removed portion of the silicon oxide layer 101 can have a lateral dimension (e.g., a width) dl distanced from the opening 201, as shown in FIG. 7, to expose a lateral dimension (equals to dl) of the surface portion of the semiconductor substrate 100. The exposed lateral dimension dl can be, e.g., less than about 500 Å, such as about 50 Å, 100 Å, 200 Å, 300 Å, 400 Å, or 450 Å.

The lateral dimension dl of the removed portion of the silicon oxide layer can be adjusted by etching time or etchant concentration used for the wet etching. In addition, by using wet etching process, damages to the semiconductor substrate 100 can be avoided.

Referring to FIG. 8, the silicon nitride layer 102 can be laterally etched from the opening 201 to remove a portion of the silicon nitride layer 102 on both sides of the opening 201 (e.g., in Step 1408).

The silicon nitride layer 102 can be laterally etched along a direction parallel to the top surface of the semiconductor substrate 100, e.g., by a wet etching process. The wet etching process may use warm phosphoric acid solution as an etchant. Portions of the laterally etched silicon nitride layer 102 can be removed to expose surface portions of silicon oxide layer 101 and surface portions of semiconductor substrate 100 on both sides of the opening 201. The laterally removed portion of the silicon nitride layer 102 can have a lateral dimension (e.g., a width) d2 distanced from the opening 201 as shown in FIG. 8. In one embodiment, the lateral dimension d2 may be greater than the lateral dimension dl as indicated in FIG. 8. The lateral dimension d2 can be, e.g., less than about 500 Å, for example, about 50 Å, about 100 Å, about 200 Å, about 300 Å, about 400 Å, or about 450 Å.

By the lateral etching of the silicon oxide layer 101 and silicon nitride layer 102, top portion of the opening 201 can have an increased width, which increases the opening for subsequently depositing insulating material in the trench 301 and the opening 201. The wider opening can reduce difficulties for depositing the insulating material. Quality of the subsequently deposited insulating material in the trench and/or quality of the STI structure can be improved. For example, voids can be avoided in the subsequently formed STI structure(s).

In this manner, the silicon oxide layer 101 can be laterally etched, followed by lateral etching of the silicon nitride layer 102. The laterally removed portions (having a lateral dimension d2) of silicon nitride layer 102 can have more amount than the laterally removed portions (having a lateral dimension d1) of the silicon oxide layer 101.

In another embodiment, the lateral dimension d2 of the removed portion of the silicon nitride layer can equal to the lateral dimension d1 of the removed portion of silicon oxide layer on a same side of the opening 201.

In another embodiment, the silicon nitride layer 102 can be laterally etched first, followed by a lateral etching of the silicon oxide layer 101. Lateral dimension d2 of the removed portion of the silicon nitride layer can be greater than or equal to lateral dimension d1 of the removed portion of silicon oxide layer on a same side of the opening 201.

Optionally, the mask layer 110 is a single layer (rather than having a double layer including silicon nitride layer 102 and silicon oxide layer 101). The mask layer 110 of a single layer can be laterally etched for one time having a lateral dimension of a removed portion on a side of the opening 201 of less than about 500 Å.

Therefore, when lateral dimension d2 is greater than lateral dimension d1, the width at a top portion of the opening 201 is further increased. Optionally, the width from top of the opening 201 to bottom of the trench 301 can be changed in a stepwise fashion. Alternatively, the width can be gradually reduced from top of the opening 201 to bottom of the trench 301. These can facilitate subsequent formation of high quality insulating material in the trench 301.

Referring to FIG. 9, a liner oxide layer 302 can be formed on sidewall surfaces and bottom surface of the trench 301 and on surface portions of the semiconductor substrate 100 exposed by the silicon oxide layer 101 (e.g., in Step 1410).

The liner oxide layer 302 can be, e.g., a silicon oxide layer made by a thermal oxidation process. The liner oxide layer 302 can have a thickness of about 5 nm or greater. The thermal oxidation process can be a wet oxidation or a dry oxidation.

In one embodiment, the liner oxide layer 302 can be formed by a dry or wet oxidation process at a reaction temperature ranging from about 600° C. to about 1200° C., for example, from about 900° C. to about 1200° C. Although the growth rate for forming the liner oxide layer 302 may be slow by dry oxidation process, the thickness of the liner oxide layer 302 can be easily controlled by dry oxidation process. In addition, the resulted liner oxide layer 302 can have high density when using the dry oxidation process.

As disclosed, the mask layer 110 can be laterally etched to expose surface portions of the semiconductor substrate and the opening 201 can be wide at the top portion. When forming the liner oxide layer 302 using the thermal oxidation process, oxygen amount supplied and consumed at the upper corner between the semiconductor substrate 100 and the trench 301 can be increased due to the wide opening. More silicon can then be consumed for the thermal oxidation process and a rounded corner structure can be formed between the top surface of the semiconductor structure 100 and the trench 301 after the liner oxide layer 302 is formed. Under high voltages, the rounded corner can provide decreased electric density to avoid leakage current and thus to increase insulation effect of the STI structure. In addition, the rounded corner can reduce stress therein and also improve quality of the liner oxide layer and the subsequently deposited insulating material in the trench for forming the STI structure.

In various embodiments, the liner oxide layer can be fabricated by thermal oxidation process using water vapor as oxidation gas or using mixture of water vapor and oxygen as oxidation gas.

In some cases, insulating material(s) to be filled in the trench 301 may not have desired adhesion with sidewalls of the trench 301, and voids may be generated. The liner oxide layer 302 provides suitable adhesion between the insulating material to be filled in the trench 301 and the sidewall of the trench 301 to avoid voids. In addition, the liner oxide layer 302 can avoid stresses generated due to mismatched lattice of the insulating material to be filled and the sidewall of the trench 301. Further, the liner oxide layer 302 can repair damages made to the surface of the trench 301 and to improve insulation effect of the subsequently formed STI.

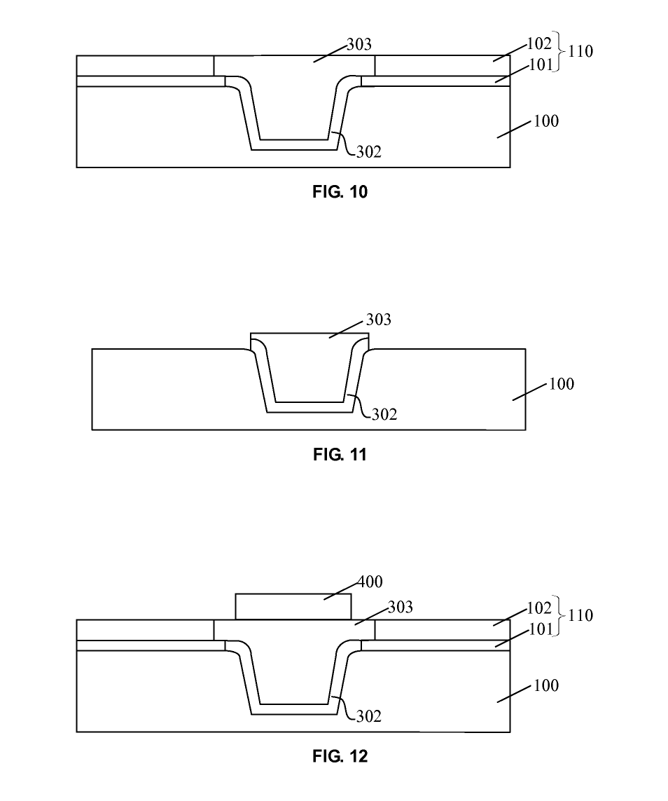

Referring to FIG. 10, insulation layer 303 is formed on surface of the liner oxide layer 302 by filling the trench 301 with insulating material(s) (e.g., in Step 1412).

For example, an insulating material can be deposited on surface of the liner oxide layer 302 to fill the trench 301 and the opening 201 and to cover the surface of the mask layer 110. The insulating material can then be planarized by chemical mechanical planarization (CMP) using the mask layer 110 as a stop layer for the CMP to form the insulation layer 303. In one embodiment, the insulating material is silicon oxide.

Various deposition methods can be used to fill the insulating material in the trench 302 and the opening 201. The deposition methods can include: chemical vapor deposition, plasma chemical vapor deposition, and/or flowable chemical vapor deposition. In other embodiments, an annealing process can be performed after deposition of the insulating material to remove defects in the deposited insulating material. Then, the planarization process can be performed. The insulation layer 303 together with the liner oxide layer 302 can form an STI structure.

Referring to FIG. 11, the mask layer 110 can be removed. In one embodiment, the mask layer 110 can be removed by a wet etching process. For example, the silicon nitride layer 102 can be removed by a phosphoric acid solution, followed by removal of the silicon oxide layer 101 by a hydrofluoric acid solution.

In one embodiment, the insulation layer 303 and the liner oxide layer 302 can be made of silicon oxide. When etching silicon oxide layer 101 by a wet etching process, a portion of insulation layer 303 can be etched away together, resulting in a reduction in height and in width of the insulation layer 303. Meanwhile, portions of liner oxide layer 302 and insulation layer 303 that are located on surface of the semiconductor substrate can be removed as shown in FIG. 11. This can prevent decrease of active area on both sides of the STI structure.

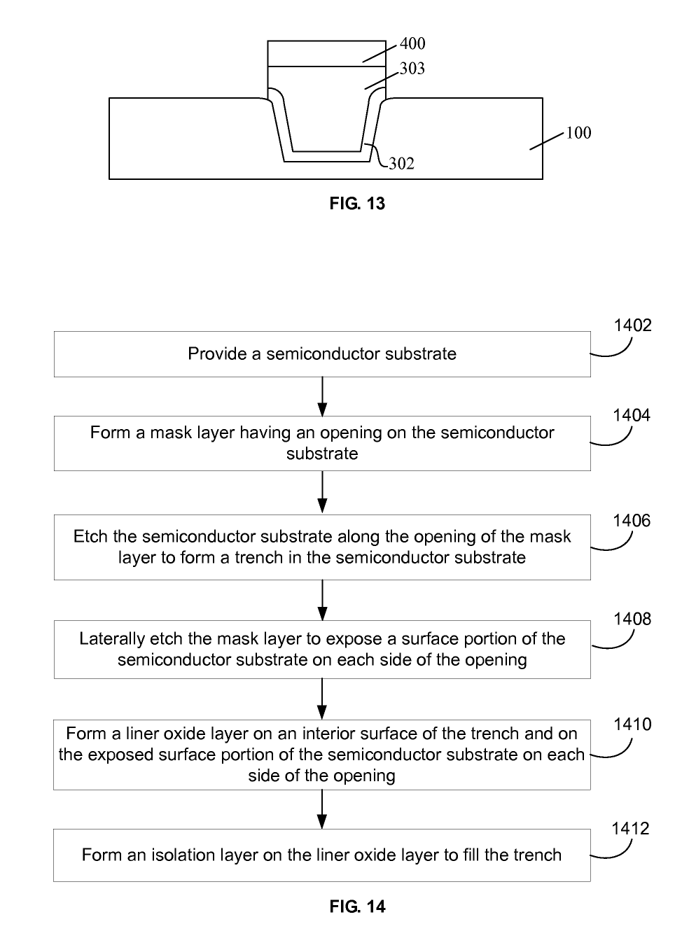

In other embodiments, as shown in FIGS. 12-13, the mask layer 110 can be removed after a photoresist layer or hard mask layer is formed on top of the insulation layer 303. Referring to FIG. 12, photoresist layer 400 is formed on the insulation layer 303 of FIG. 10.

The photoresist layer 400 can have a width equal to a width of a top surface of the trench 301. Alternatively, the insulation layer 303 may have a top surface having a width greater than the width of the top surface of the trench 301. When subsequently using the photoresist layer 400 as an etch mask to remove the mask layer 100, portions of the oxide layer 302 and the insulation layer 303 that are on top surface of the semiconductor substrate 100 can be removed together.

Referring to FIG. 13, the mask layer 110 is removed using the photoresist layer 400 as an etch mask. The mask layer 110 can be removed by a wet etching process or dry etching process. By forming the photoresist layer 400 on surface of the insulation layer 303, height reduction of the insulation layer can be avoided. The insulation layer 303 with greater height can be used to adjust pattern density for a subsequent fabrication of other devices on the semiconductor substrate. Optionally, the photoresist layer 400 can be removed, e.g., by an ashing process.

Various embodiments can include a semiconductor device having an STI structure. For example, as shown in FIG. 11, an STI structure can include: a semiconductor substrate 100 and a trench in the semiconductor substrate 100 having a rounded corner between top surface of the semiconductor substrate and sidewall of the trench. The STI structure can also include a liner oxide layer 302 positioned on interior surfaces of the trench, and an insulation layer 303 deposited on surface of the liner oxide layer to completely fill the trench.

The rounded corner between top surface of the semiconductor substrate and sidewall of the trench can provide decreased electric density to avoid leakage current when in operation and thus to increase insulation effect of the STI structure. In addition, the rounded corner can also reduce stress therein, and increase quality of the formed liner oxide layer and the subsequently deposited insulating material in the trench for forming desired STI structure.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A method for forming a semiconductor device, comprising:
providing a semiconductor substrate;
forming a mask layer having an opening on the semiconductor substrate;
etching the semiconductor substrate along the opening of the mask layer to form a trench in the semiconductor substrate;
laterally etching the mask layer from the opening of the mask layer and along a top surface of the semiconductor substrate to expose a surface portion of the semiconductor substrate on each side of the opening;
forming a liner oxide layer using a thermal oxidation process on an interior surface of the trench and on the exposed surface portion of the semiconductor substrate on each side of the opening, wherein the thermal oxidation process is controlled such that an upper corner between the top surface of the semiconductor substrate and the trench is rounded after the liner oxide layer is formed; and
forming an insulation layer on the liner oxide layer, wherein the insulation layer fills the trench.

2. The method according to claim 1, wherein the mask layer is laterally etched along the top surface of the semiconductor substrate on each side of the opening to remove a portion having a lateral dimension of less than about 500 Å.

3. The method according to claim 1, wherein the mask layer comprises a silicon oxide layer formed on the top surface of the semiconductor substrate and a silicon nitride layer formed on the silicon oxide layer.

4. The method according to claim 3, wherein the mask layer is laterally etched by:
using a wet etching process to laterally remove a portion of the silicon oxide layer by a lateral dimension of less than about 500 Å on each side of the opening; and
using a wet etching process to laterally remove a portion of the silicon nitride layer by a lateral dimension of less than about 500 Å on each side of the opening,
wherein the lateral dimension of the removed portion of the silicon oxide layer is less than or equal to the lateral dimension of the removed portion of the silicon nitride layer on each side of the opening.

5. The method according to claim 4, wherein the mask layer is laterally etched by first etching the silicon oxide layer and then etching the silicon nitride layer.

6. The method according to claim 4, wherein the mask layer is laterally etched by first etching the silicon nitride layer and then etching the silicon oxide layer.

7. The method according to claim 4, wherein the silicon oxide layer is etched by a hydrofluoric acid solution and the silicon nitride layer is etched by a phosphoric acid solution.

8. The method according to claim 1, wherein the liner oxide layer is formed by a wet oxidation process or a dry oxidation process.

9. The method according to claim 1, wherein the liner oxide layer is formed to have a thickness of about 5 nm or greater.

10. The method according to claim 1, wherein the liner oxide layer is formed by a dry oxidation process at a temperature of about 600° C. to about 1200° C.

11. The method according to claim 1, wherein the insulation layer is formed by:
depositing an insulating material on a surface of the liner oxide layer to fill the trench and to cover a top surface of the mask layer; and
planarizing the insulating material using the mask layer as a stop layer to form the insulation layer.

12. The method according to claim 1, wherein the insulation layer is formed by one or more of a chemical vapor deposition, a plasma chemical vapor deposition, and a flowable chemical vapor deposition.

13. The method according to claim 1, further comprising: removing the mask layer using a wet etching after the insulation layer is formed.

14. The method according to claim 11, further comprising:
forming a photoresist layer on a surface portion of the insulation layer; and
using the photoresist layer as an etch mask to remove: the mask layer, a portion of the liner oxide layer on the surface portion of the semiconductor substrate on both sides of the opening, and a portion of the insulation layer on the portion of the liner oxide layer on the surface portion of the semiconductor substrate on both sides of the opening.

15. A semiconductor device, comprising:
a semiconductor substrate;
a liner oxide layer disposed on sidewall surfaces and a bottom surface of a trench in the semiconductor substrate,
wherein the liner oxide layer is obtained by forming a mask layer having an opening on the semiconductor substrate, etching the semiconductor substrate along the opening of the mask layer to form the trench, laterally etching the mask layer from the opening of the mask layer and along a top surface of the semiconductor substrate to expose a surface portion of the semiconductor substrate, and forming the liner oxide layer on an interior surface of the trench and on the exposed surface portion of the semiconductor substrate, and
wherein the liner oxide layer is formed by a thermal oxidation process controlled such that an upper corner between a top surface of the semiconductor substrate and the trench is a rounded corner after forming the liner oxide layer; and
an insulation layer disposed on the liner oxide layer, wherein the insulation layer fills the trench.

16. The device according to claim 15, wherein the liner oxide layer has a thickness of about 5 nm or greater.

17. The device according to claim 15, wherein each of the liner oxide layer and the insulation layer is protruded from a top surface of a top surface of the semiconductor substrate by a thickness greater than about 5 nm.

18. The device according to claim 15, wherein the liner oxide layer has a rounded corner when connecting with the top surface of the semiconductor substrate.

19. The device according to claim 15, wherein the mask layer comprises a silicon oxide layer formed on the top surface of the semiconductor substrate and a silicon nitride layer formed on the silicon oxide layer.

20. The device according to claim 19, wherein the insulation layer is made of silicon oxide.
